(19) United States
(12) Patent Application Publication
(10) Pub. No.: US 2018/0197829 A1
(43) Pub. Date: Jul. 12, 2018

(54) THREE-DIMENSIONAL INTEGRATED CIRCUIT ASSEMBLY WITH ACTIVE INTERPOSER

(71) Applicant: Qorvo US, Inc., Greensboro, NC (US)

(72) Inventor: Wolfram C. Stiebler, Munich (DE)

(21) Appl. No.: 15/656,024

(22) Filed: Jul. 21, 2017

Related U.S. Application Data
(60) Provisional application No. 62/443,864, filed on Jan. 9, 2017.

(51) Int. Cl. H01L 23/66; H01L 23/498; H01L 23/552; H01L 23/367; H01L 21/48

(52) U.S. Cl. CPC H01L 23/66; H01L 23/49838; H01L 23/552; H01L 23/3675; H01L 23/49827; H01L 23/49822; H01L 25/0655; H01L 21/4857; H01L 21/4853; H01L 21/486; H01L 21/4875; H01L 2223/6677; H01L 2223/6616; H01L 23/49833

(57) ABSTRACT

Embodiments of the disclosure relate to a three-dimensional (3D) integrated circuit (IC) (3DIC) assembly with active interposer. The 3DIC assembly includes an antenna substrate having at least one electromagnetic radiating structure (e.g., an antenna) and a carrier substrate having layered conductive interconnects. An active interposer(s) is formed by a semiconductor IC chip(s) and disposed between the antenna substrate and the carrier substrate to conductively couple the antenna substrate with the carrier substrate. The active interposer is coupled to the electromagnetic radiating structure in the antenna substrate through a conductive path that penetrates the antenna substrate, but not going through the carrier substrate. As such, it is possible to reduce routing distance between the active interposer and the electromagnetic radiating structure, thus helping to reduce path loss and/or electromagnetic signal interference to improve heat dissipation and power consumption of the 3DIC assembly.

### RELATED APPLICATIONS

This application claims the benefit of Provisional Patent Application Ser. No. 62/443,864, filed Jan. 9, 2017, the disclosure of which is hereby incorporated herein by reference in its entirety.

### FIELD OF THE DISCLOSURE

The technology of the disclosure relates generally to a three-dimensional integrated circuit (3DIC).

### BACKGROUND

To enable high-performing electronic systems for wireless communication and sensing applications, radio frequency (RF) front-end and antenna sub-systems may be integrated and packaged to minimize losses while maintaining signal integrity over all relevant electro-thermal conditions. Considerations over such factors as power efficiency, product size, and production cost lead to the adaptation of low-loss packaging technologies that can reduce routing distances and allow for control of electrical impedances along signal paths as well as through interconnects.

Multi-layered substrates of various materials are preferred carriers for integrating microelectronic and/or optoelectronic devices into a three-dimensional (3D) low-loss package. The multi-layered substrates allow 3D routing options to be provided through layer-to-layer interconnects or vias, as well as integrated RF functions to be provided through embedded electromagnetic structures in the 3D low-loss package. Accordingly, active and passive components are attached to the carrier by means of various methods (e.g. solder, epoxy, etc.), creating a module that can be conveniently used in a higher level assembly of an electronic solution.

### SUMMARY

Embodiments of the disclosure relate to a three-dimensional (3D) integrated circuit (IC) (3DIC) assembly with active interposer. The 3DIC assembly includes an antenna substrate having at least one electromagnetic radiating structure (e.g., an antenna) and a carrier substrate having layered conductive interconnects. An active interposer(s) is formed by a semiconductor IC chip(s) and disposed between the antenna substrate and the carrier substrate to conductively couple the antenna substrate with the carrier substrate. The active interposer(s) is coupled to the electromagnetic radiating structure in the antenna substrate through a conductive path that penetrates the antenna substrate, but not going through the carrier substrate. As such, it is possible to reduce routing distance between the active interposer(s) and the electromagnetic radiating structure, thus helping to reduce path loss and/or electromagnetic signal interference to improve heat dissipation and power consumption of the 3DIC assembly.

In one aspect, a 3DIC assembly is provided. The 3DIC assembly includes an antenna substrate comprising a multilayer substrate and at least one electromagnetic radiating structure formed in or on the multilayer substrate. The 3DIC assembly also includes a carrier substrate comprising layered conductive interconnects. The 3DIC assembly also includes at least one active interposer formed by at least one semiconductor IC chip and disposed between the antenna substrate and the carrier substrate to conductively couple the antenna substrate with the carrier substrate. The at least one active interposer is coupled to the at least one electromagnetic radiating structure through a conductive path penetrating the antenna substrate and independent from the carrier substrate.

In another aspect, a method for fabricating a 3DIC assembly is provided. The method includes fabricating an antenna substrate comprising a multilayer substrate and at least one electromagnetic radiating structure formed in or on the multilayer substrate. The method also includes fabricating a carrier substrate comprising layered conductive interconnects. The method also includes forming at least one active interposer using at least one semiconductor IC chip. The method also includes disposing the at least one active interposer between the antenna substrate and the carrier substrate to conductively couple the antenna substrate with the carrier substrate. The method also includes coupling the at least one active interposer to the at least one electromagnetic radiating structure through a conductive path penetrating the antenna substrate and independent from the carrier substrate.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1A is a schematic diagram of an exemplary conventional three-dimensional (3D) integrated circuit (IC) (3DIC) assembly in which a radio frequency (RF) IC (RFIC) is conductively coupled to an antenna via conductive interconnects in an interposer;

FIG. 1B is a schematic diagram of an exemplary conventional 3DIC assembly in which an RFIC is conductively coupled to an antenna via layered conductive interconnects in a carrier substrate;

FIG. 2 is a schematic diagram of an exemplary 3DIC assembly having at least one active interposer disposed between an antenna substrate and a carrier substrate to conductively couple the antenna substrate with the carrier substrate;

FIG. 3 is a schematic diagram of an exemplary RF communication system that can be fabricated into the 3DIC assembly of FIG. 2; and

FIG. 4 is a flowchart of an exemplary process for fabricating the 3DIC assembly of FIG. 2.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a three-dimensional (3D) integrated circuit (IC) (3DIC) assembly with active interposer. The 3DIC assembly includes an antenna substrate having at least one electromagnetic radiating structure (e.g., an antenna) and a carrier substrate having layered conductive interconnects. An active interposer(s) is formed by a semiconductor IC chip(s) and disposed between the antenna substrate and the carrier substrate to conductively couple the antenna substrate with the carrier substrate. The active interposer(s) is coupled to the electromagnetic radiating structure in the antenna substrate through a conductive path that penetrates the antenna substrate, but not going through the carrier substrate. As such, it is possible to reduce routing distance between the active interposer(s) and the electromagnetic radiating structure, thus helping to reduce path loss and/or electromagnetic signal interference to improve heat dissipation and power consumption of the 3DIC assembly.

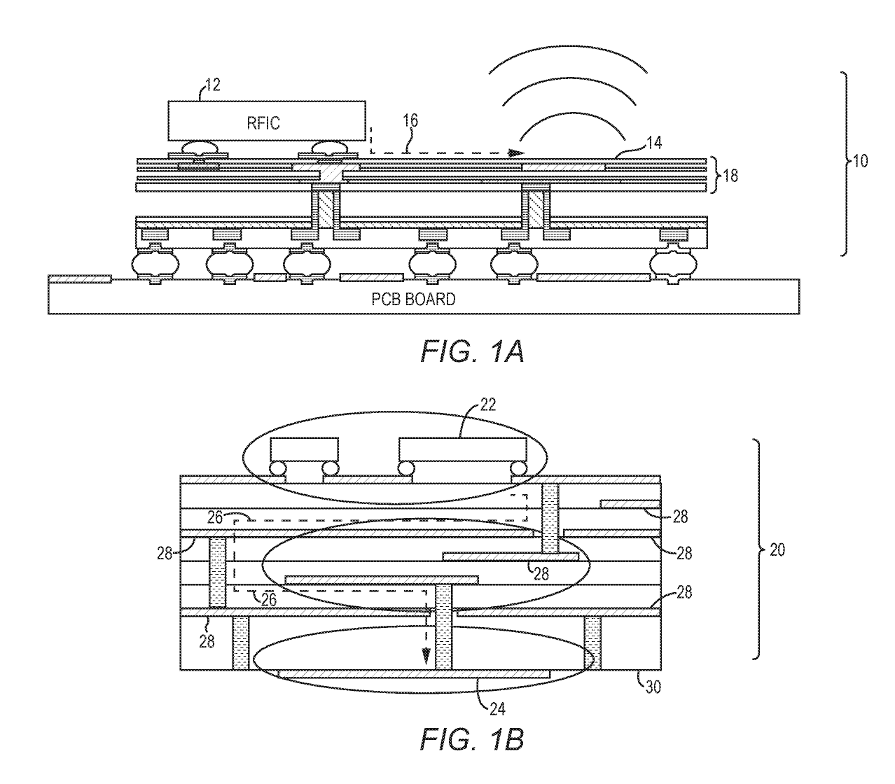

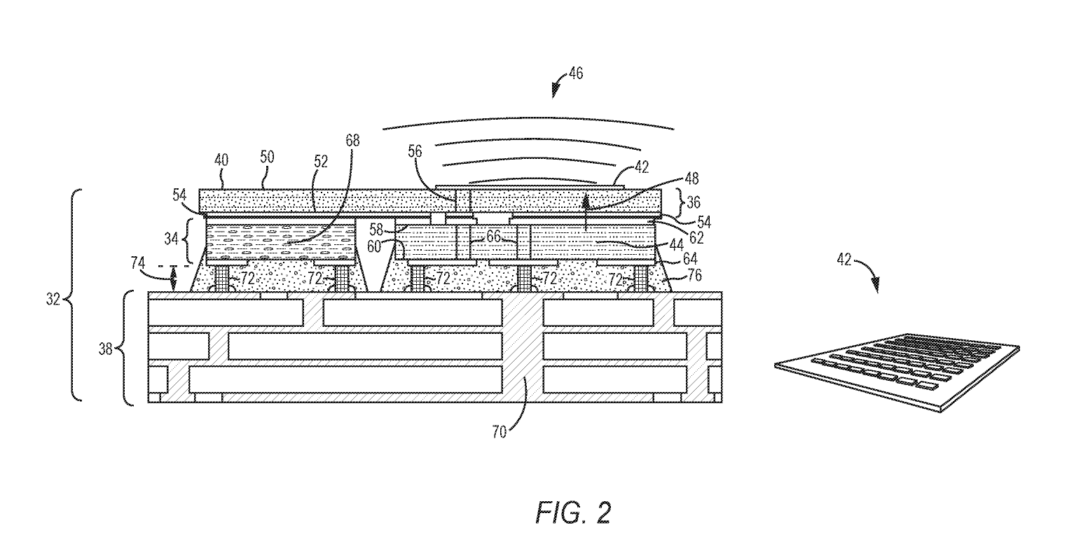

Before discussing exemplary aspects of a 3DIC assembly with active interposer, a brief overview of a conventional 3DIC assembly in which an RFIC is coupled to an antenna through an interposer is first provided with reference to FIG. 1A. A brief overview of another conventional 3DIC assembly in which an RFIC is coupled to an antenna through conductive interconnects in a carrier substrate is then provided with reference to FIG. 1B. The discussion of specific exemplary aspects of a 3DIC assembly with active interposer starts below with reference to FIG. 2.

FIG. 1A is a schematic diagram of an exemplary conventional 3DIC assembly 10 in which an RFIC 12 is conductively coupled to an antenna 14 via a conductive path 16 routed through an interposer 18. As shown in FIG. 1A, the RFIC 12 is disposed side-by-side with the antenna. Accordingly, the RFIC 12 is coupled to the antenna 14 via the conductive path 16 that is routed horizontally through the interposer 18. Notably, the RFIC 12 needs to be physically separated from the antenna 14 by a sufficient separation distance to help reduce potential electromagnetic interference. Therefore, the conductive path 16 needs to be sufficiently long to provide the sufficient separation distance.

FIG. 1B is a schematic diagram of an exemplary conventional 3DIC assembly 20 in which an RFIC 22 is conductively coupled to an antenna 24 via a conductive path 26 routed through layered conductive interconnects 28 in a carrier substrate 30. As shown in FIG. 1B, the RFIC 22 and the antenna 24 are disposed on opposing sides of the carrier substrate 30. Accordingly, the RFIC 22 is coupled to the antenna 24 via the conductive path 26 that traverses through the layered conductive interconnects 28 in the carrier substrate 30.

As discussed above, the conductive path 16 of FIG. 1 A and the conductive path 26 of FIG. 1B are both relatively long, which can lead to increased path loss and/or electromagnetic signal interference between an RFIC (e.g., the RFIC 12 of FIG. 1A or the RFIC 22 of FIG. 1B) and an antenna (e.g., the antenna 14 of FIG. 1A or the antenna 24 of FIG. 1B). As such, it may be desired to couple an RFIC to an antenna via a shortest possible conductive path to help reduce the path loss and/or the electromagnetic signal interference, while providing sufficient electromagnetic shielding between the RFIC and the antenna.

In this regard, FIG. 2 is a schematic diagram of an exemplary 3DIC assembly 32 having at least one active interposer 34 disposed between an antenna substrate 36 and a carrier substrate 38 to conductively couple the antenna substrate 36 with the carrier substrate 38. In examples discussed herein, the active interposer 34 can be formed by a semiconductor IC chip(s) (e.g., an RFIC and/or a processing IC). In this regard, the active interposer 34 is different from a conventional interposer that includes only a conductive interconnect(s) and/or a passive component(s). As discussed below, the active interposer 34 allows heterogeneous integration of semiconductor technologies, devices, and antenna systems in the 3DIC 32, while providing additional 3D routing options to help improve performance and reduce footprint of the 3DIC assembly 32. Further, by attaching the active interposer 34 directly to the antenna substrate 36, it is also possible to provide electromagnetic shielding for the antenna substrate 36 and a low-resistance path(s) for thermal dissipation. As such, the 3DIC assembly 32 can be fabricated to support advanced wireless communications systems, such as a fifth-generation (5G) wireless communications system, that rely heavily on multiple-input multiple-output (MIMO) and/or RF beamforming technologies.

The antenna substrate 36 includes a multilayer substrate 40, which can be a laminate substrate for example. The antenna substrate 36 also includes at least one electromagnetic radiating structure 42 disposed in or on the multilayer substrate 40. In a non-limiting example, the electromagnetic radiating structure 42 can be an antenna or an antenna array capable of supporting the MIMO and/or the RF beamforming technologies for the 5G wireless communications system. Notably, the electromagnetic radiating structure 42 can be a patch antenna or any other form of antenna as deemed suitable for an intended wireless communications system.

The active interposer 34 is formed by at least one semiconductor IC chip 44, which can be an RF front-end IC for example, for communicating a wireless communication signal(s) 46 through the electromagnetic radiating structure 42. The active interposer 34 is directly coupled to the electromagnetic radiating structure 42 via a conductive path 48 that penetrates the antenna substrate 36, without going through the carrier substrate 38. In this regard, the conductive path 48 is also said to be independent from the carrier substrate 38. Accordingly, the RF front-end IC can control the electromagnetic radiating structure 42 through the conductive path 48.

Although the 3DIC assembly 32 is shown in FIG. 2 to include only one active interposer 34, it should be appreciated that the example is by no means limiting. In fact, the 3DIC assembly 32 may include multiple active interposers. For example, an additional semiconductor IC layer can be disposed between the active interposer 34 and the antenna substrate 36, with a second active interposer being disposed between the additional semiconductor IC layer and the antenna substrate 36. In this regard, the conductive path 48 would penetrate the additional semiconductor IC layer, the second active interposer, and the antenna substrate 36 to couple the active interposer 34 to the electromagnetic radiating structure 42.

Given that the conductive path 48 is routed directly through the antenna substrate 36, the conductive path 48 would be shorter than the conductive path 16 in FIG. 1A, which is routed horizontally along the interposer 18. Further, since the conductive path 48 is not routed through the carrier substrate 38, the conductive path 48 would be significantly shorter than the conductive path 26 in FIG. 1B. Thus, by providing the conductive path 48 directly between the active interposer 34 and the electromagnetic radiating structure 42, it is possible to reduce routing distance between the active interposer 34 and the electromagnetic radiating structure 42. As a result, it is possible to reduce path loss and/or electromagnetic signal interference associated with the conductive path 16 of FIG. 1A and the conductive path 26 of FIG. 1B, thus leading to improved heat dissipation and power consumption in the 3DIC assembly 32.

The antenna substrate 36 has a front-side surface 50 and a back-side surface 52. In a non-limiting example, the electromagnetic radiating structure 42 is formed on the front-side surface 50 to facilitate transmission and/or reception of the wireless communication signal(s) 46. A metallization plate 54 is disposed on the back-side surface 52 of the antenna substrate 36. The antenna substrate 36 includes at least one conductive via 56 extending from the front-side surface 50 to the back-side surface 52 of the antenna substrate 36. In this regard, the conductive via 56 provides conductive coupling between the electromagnetic radiating structure 42 and the metallization plate 54 in the antenna substrate 36. The metallization plate 54 can provide electromagnetic shielding for the electromagnetic radiating structure 42. In addition, the metallization plate 54 can serve as a first heat sink in the 3DIC assembly 32 to help provide heat dissipation.

The active interposer 34 includes a first surface 58 and a second surface 60. A first patterned metallization layer 62 and a second patterned metallization layer 64 are disposed on the first surface 58 and the second surface 60 of the active interposer 34, respectively. In a non-limiting example, materials such as gold (Gu) and tin (Sn) can be used to form patterned eutectic alloy in the first patterned metallization layer 62 and the second patterned metallization layer 64 to provide desirable electro-thermal and mechanical properties. The active interposer 34 includes a plurality of conductive vias 66, which extend from the first surface 58 to the second surface 60, to conductively couple the first patterned metallization layer 62 with the second patterned metallization layer 64.

The active interposer 34 may be provided on the back-side surface 52 of the antenna substrate 36. More specifically, the metallization plate 54 on the back-side surface 52 of the antenna substrate 36 is bonded to the first patterned metallization layer 62 of the active interposer 34 by a solder patch, as an example. Accordingly, the active interposer 34 can be conductively coupled to the electromagnetic radiating structure 42 via the conductive path 48 formed by the first patterned metallization layer 62, the metallization plate 54, and the conductive via 56 in the antenna substrate 36.

In a non-limiting example, the active interposer 34 can also be formed by a processing IC chip 68 in addition to the semiconductor IC chip 44. The processing IC chip 68 may be a digital baseband IC chip, a processor IC chip, a control circuit IC chip, or a combination of IC chips for supporting signal processing in the 3DIC assembly 32. The semiconductor IC chip 44 and/or the processing IC chip 68 may be fabricated using appropriate passive or active technology, such as Gallium Nitride (GaN), Gallium Arsenide (GaAs), Silicon on Insulator (SOI), Silicon Germanium (SiGe), Complementary Metal-Oxide Semiconductor (CMOS), Bipolar CMOS, etc.

The carrier substrate 38, which can be a multi-layered laminate, includes layered conductive interconnects 70. The multi-layered laminate may be formed by such materials as a composite of glass/epoxy or a polyimide resin of ceramic-filled hydrocarbon polymer. The carrier substrate 38 can be bonded to the second patterned metallization layer 64 of the active interposer 34 by one or more conductive structures 72. In a non-limiting example, the conductive structures 72 can be formed in a pillar style (solder pillar) or a ball style (solder ball) using such material as copper (Cu). The conductive structures 72 are conductively coupled to the layered conductive interconnects 70 in the carrier substrate. As such, the layered conductive interconnects 70 in the carrier substrate 38 can be conductively coupled to the active interposer 34, the antenna substrate 36, and thus the electromagnetic radiating structure 42. The layered conductive interconnects 70 may be conductively coupled to IC chips external to the 3DIC assembly 32, thus allowing the semiconductor IC chip 44 and/or the processing IC chip 68 to communicate with the IC chips external to the 3DIC assembly 32.

Notably, the conductive structures 72 can create a gap 74 between the second patterned metallization layer 64 of the active interposer 34 and the carrier substrate 38. In a non-limiting example, the gap 74 can be filled by an over-molding 76 using a material having defined electromagnetic and electro-thermal properties. The over-molding 76 may be formed through capillary action or by dispensing the material using pressure (molding). Thus, by filling the gap 74 with the over-molding 76, it is possible improve thermal energy transfer in the 3DIC assembly 32 in addition to providing enhanced mechanical integrity of the 3DIC assembly 32. As such, the carrier substrate 38 can provide a second heat sink for the 3DIC assembly 32.

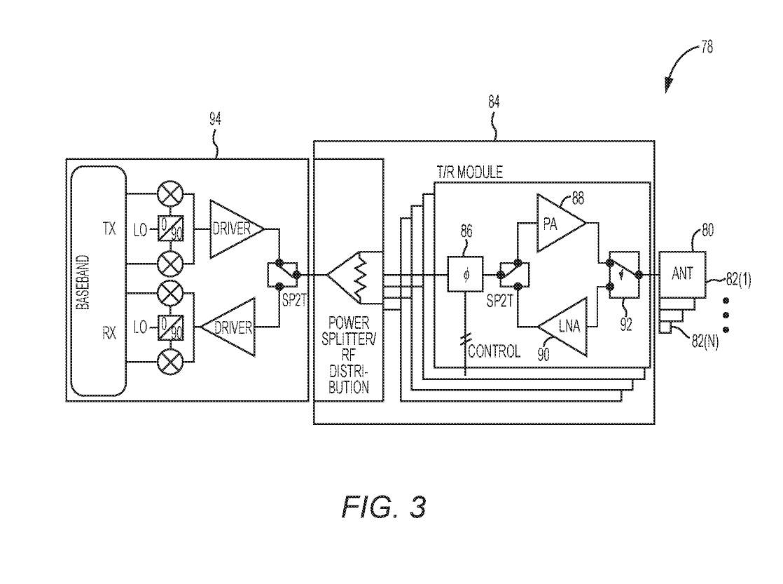

The 3DIC assembly 32 can be fabricated to provide functionalities of an RF communication system as shown in FIG. 3. In this regard, FIG. 3 is a schematic diagram of an exemplary RF communication system 78 that can be fabricated into the 3DIC assembly 32 of FIG. 2.

The RF communication system 78 includes an antenna array 80 that includes a plurality of antennas 82(1)-82(N). The antennas 82(1)-82(N) can be configured to support MIMO and/or RF beamforming. The RF communication system 78 also includes an RF front-end circuit 84, which can include such components as a phase shifter 86, a power amplifier (PA) 88, a low-noise amplifier (LNA) 90, and an RF switch 92. The RF communication system 78 can also include a processing circuit 94 for processing the wireless communication signal(s) 46 of FIG. 2 and/or controlling operations of the RF front-end circuit 84. In a non-limiting example, the antenna array 80 can be provided on or in the antenna substrate 36 of the 3DIC assembly 32. The RF front-end circuit 84 and the processing circuit 94 can be provided in the active interposer 34 in the 3DIC assembly 32.

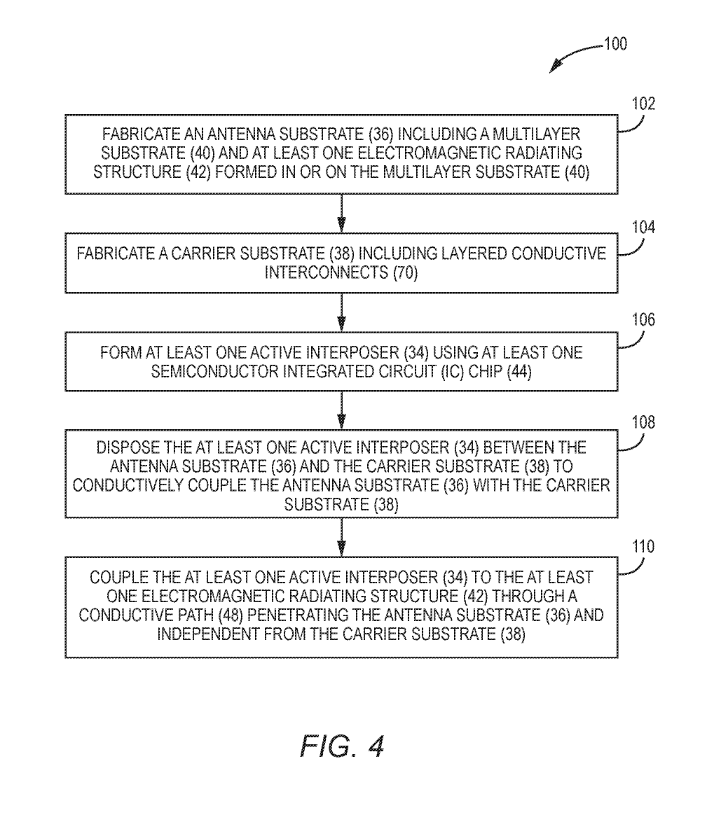

The 3DIC assembly 32 of FIG. 2 can be fabricated according to a process. In this regard, FIG. 4 is a flowchart of an exemplary process 100 for fabricating the 3DIC assembly 32 of FIG. 2.

According to the process 100, the antenna substrate 36 is fabricated to include the multilayer substrate 40 and the electromagnetic radiating structure 42 formed in or on the multilayer substrate 40 (block 102). The electromagnetic radiating structure 42 may be disposed on the front-side surface 50 of the multilayer substrate 40. The metallization plate 54 may be disposed on the back-side surface 52 of the multilayer substrate 40. The conductive via 66 can be provided in the multilayer substrate 40 to conductively couple the electromagnetic radiating structure 42 to the metallization plate 54.

The carrier substrate 38 is fabricated to include the layered conductive interconnects 70 (block 104). The active interposer 34 is formed using the semiconductor IC chip 44 (block 106). The first patterned metallization layer 62 and the second patterned metallization layer 64 are disposed on the first surface 58 and the second surface 60 of the active interposer 34, respectively. The conductive vias 66 are provided in the active interposer 34 to conductively couple the first patterned metallization layer 62 with the second patterned metallization layer 64.

The active interposer 34 is disposed between the antenna substrate 36 and the carrier substrate 38 to conductively couple the antenna substrate 36 with the carrier substrate 38 (block 108). The first patterned metallization layer 62 on the first surface 58 of the active interposer 34 is conductively bonded to the metallization plate 54 on the back-side surface 52 of the multilayer substrate 40. The carrier substrate 38 is bonded to the second patterned metallization layer 64 on the second surface 60 of the active interposer 34 through the conductive structures 72. The gap 74 between the second patterned metallization layer 64 and the carrier substrate 38 is filled by the over-molding 76. Accordingly, the active interposer 34, and thus the semiconductor IC chip 44, is coupled to the electromagnetic radiating structure 42 through the conductive path 48 that penetrates the antenna substrate 36 and is independent from the carrier substrate 38 (block 110).

Those skilled in the art will recognize improvements and modifications to the preferred embodiments of the present disclosure. All such improvements and modifications are considered within the scope of the concepts disclosed herein and the claims that follow.

What is claimed is:

1. A three-dimensional (3D) integrated circuit (IC) (3DIC) assembly comprising:
an antenna substrate comprising a multilayer substrate and at least one electromagnetic radiating structure formed in or on the multilayer substrate;
a carrier substrate comprising layered conductive interconnects; and
at least one active interposer formed by at least one semiconductor IC chip and disposed between the antenna substrate and the carrier substrate to conductively couple the antenna substrate with the carrier substrate, the at least one active interposer coupled to the at least one electromagnetic radiating structure through a conductive path penetrating the antenna substrate and independent from the carrier substrate.

2. The 3DIC assembly of claim 1 wherein the at least one active interposer is further conductively coupled to the layered conductive interconnects in the carrier substrate.

3. The 3DIC assembly of claim 1 wherein the at least one active interposer is formed by a radio frequency (RF) front-end IC chip configured to control the at least one electromagnetic radiating structure via the conductive path penetrating the antenna substrate.

4. The 3DIC assembly of claim 1 wherein the at least one active interposer is formed by a processing IC chip configured to support signal processing in the 3DIC assembly.

5. The 3DIC assembly of claim 1 wherein:
a first patterned metallization layer is disposed on a first surface of the at least one active interposer;
a second patterned metallization layer is disposed on a second surface of the at least one active interposer; and
the first patterned metallization layer is conductively coupled to the second patterned metallization layer by a plurality of conductive vias extending from the first surface to the second surface of the at least one active interposer.

6. The 3DIC assembly of claim 5 wherein:
the at least one electromagnetic radiating structure is disposed on a front-side surface of the antenna substrate;
a metallization plate is disposed on a back-side surface of the antenna substrate; and
the at least one electromagnetic radiating structure is conductively coupled to the metallization plate by at least one conductive via extending from the front-side surface to the back-side surface of the antenna substrate.

7. The 3DIC assembly of claim 6 wherein the metallization plate is configured to provide a first heat sink for the 3DIC assembly.

8. The 3DIC assembly of claim 6 wherein the metallization plate is configured to provide electromagnetic shielding for the at least one electromagnetic radiating structure.

9. The 3DIC assembly of claim 6 wherein:
the metallization plate on the back-side surface of the antenna substrate is conductively bonded to the first patterned metallization layer of the at least one active interposer; and
the at least one active interposer is conductively coupled to the at least one electromagnetic radiating structure by the first patterned metallization layer, the metallization plate, and the at least one conductive via in the antenna substrate.

10. The 3DIC assembly of claim 9 wherein the carrier substrate is bonded to the second patterned metallization layer of the at least one active interposer via one or more conductive structures coupled to the layered conductive interconnects in the carrier substrate.

11. The 3DIC assembly of claim 10 wherein a gap created by the one or more conductive structures between the second patterned metallization layer of the at least one active interposer and the carrier substrate is filled by a material having defined electromagnetic and electro-thermal properties.

12. The 3DIC assembly of claim 10 wherein the carrier substrate is configured to provide a second heat sink for the 3DIC assembly.

13. The 3DIC assembly of claim 10 wherein the layered conductive interconnects in the carrier substrate are conductively coupled to IC chips external to the 3DIC assembly.

14. A method for fabricating a three-dimensional (3D) integrated circuit (IC) (3DIC) assembly comprising:
fabricating an antenna substrate comprising a multilayer substrate and at least one electromagnetic radiating structure formed in or on the multilayer substrate;
fabricating a carrier substrate comprising layered conductive interconnects;
forming at least one active interposer using at least one semiconductor IC chip;
disposing the at least one active interposer between the antenna substrate and the carrier substrate to conductively couple the antenna substrate with the carrier substrate; and
coupling the at least one active interposer to the at least one electromagnetic radiating structure through a conductive path penetrating the antenna substrate and independent from the carrier substrate.

15. The method of claim 14 further comprising conductively coupling the at least one active interposer to the layered conductive interconnects in the carrier substrate.

16. The method of claim 14 further comprising:
disposing a first patterned metallization layer on a first surface of the at least one active interposer;
disposing a second patterned metallization layer on a second surface of the at least one active interposer; and
conductively coupling the first patterned metallization layer to the second patterned metallization layer by a plurality of conductive vias extending from the first surface to the second surface of the at least one active interposer.

17. The method of claim 16 further comprising:
disposing the at least one electromagnetic radiating structure on a front-side surface of the antenna substrate;
disposing a metallization plate on a back-side surface of the antenna substrate; and
conductively coupling the at least one electromagnetic radiating structure to the metallization plate by at least one conductive via extending from the front-side surface to the back-side surface of the antenna substrate.

18. The method of claim 17 further comprising:
conductively bonding the metallization plate on the back-side surface of the antenna substrate to the first patterned metallization layer of the at least one active interposer; and
conductively coupling the at least one active interposer to the at least one electromagnetic radiating structure by the first patterned metallization layer, the metallization plate, and the at least one conductive via in the antenna substrate.

19. The method of claim 18 further comprising bonding the carrier substrate to the second patterned metallization layer of the at least one active interposer via one or more conductive structures coupled to the layered conductive interconnects in the carrier substrate.

20. The method of claim 19 further comprising filling a gap created by the one or more conductive structures between the second patterned metallization layer of the at least one active interposer and the carrier substrate by a material having defined electromagnetic and electro-thermal properties.
